(19) United States
(12) Patent Application Publication
(10) Pub. No.: US 2023/0251699 A1
(43) Pub. Date: Aug. 10, 2023

(54) METHOD AND APPARATUS FOR MEASURING POWER SUPPLY INDUCED JITTER

(71) Applicant: Tektronix, Inc., Beaverton, OR (US)

(72) Inventors: Madhusudan Acharya, Bengaluru (IN); Yogesh M. Pai, Bengaluru (IN); Krishna N H Sri, Bengaluru (IN); Anthony B. Ambrose, Anaheim, CA (US); Blair Battye, Petrolia (CA); Dallas J. Mohler, Highlands Ranch, CO (US)

(73) Assignee: Tektronix, Inc., Beaverton, OR (US)

(21) Appl. No.: 18/105,736

(22) Filed: Feb. 3, 2023

(30) Foreign Application Priority Data
Feb. 7, 2022 (IN) 202221006430

(51) Int. Cl. G06F 1/30; G06F 1/28

(52) U.S. Cl. CPC G06F 1/305; G06F 1/28

(57) ABSTRACT

A test and measurement instrument includes components and methods for measuring noise at an output of a power supply, measuring jitter of a serial data signal produced by a data generating circuit coupled to the power supply and correlating the noise measured from the power supply to the jitter of the serial data signal. The correlation may be performed in the frequency domain. Spectral plots of the measured noise and the measured jitter may be generated and presented to the user.

### CROSS-REFERENCE TO RELATED APPLICATIONS

This application claims priority under 35 U.S.C. § 119 to Indian Provisional Patent Application No. 202221006430, filed Feb. 7, 2022, titled “METHOD AND APPARATUS FOR MEASURING POWER SUPPLY INDUCED JITTER,” the disclosure of which is incorporated herein by reference in its entirety.

### FIELD OF THE INVENTION

The present disclosure relates generally to signal quality analysis, and more particularly, relates to identifying Power Supply Induced Jitter (PSIJ) occurring in high-speed serial (HSS) data.

### BACKGROUND

In the present systems generating high-speed serial data, operating frequencies can attain values up to tens of GHz with multiple power rails turning on the different high-speed loads. Considering the scaled down supply voltages and the higher switching speeds of modem circuits, one of the most challenging tasks for modern system designers is to maintain the integrity of the high-speed data signals as they are generated and to minimize any carryover effect from imperfect power signals. This need for minimal crossover effects becomes more important as circuits reduce in size to sub-micrometer technologies which causes the power signals to become increasingly physically close to the components that generate the high-speed data signals, which exacerbates the carryover effect.

Signal integrity (SI) analysis typically focuses on the performance of a transmitter, reference clock, channel, and receiver circuits in terms of the bit error rate (BER). Conversely, Power integrity (PI) analysis typically focuses on the power distribution network’s (PDN’s) ability to provide constant power, through a series of power rails, without voltage spikes and low impedance return paths. Further, in high-speed systems, the PI and SI systems are somewhat interdependent, so that changes in PI may also affect the quality of the SI. Also, the PDN can cause noise and jitter itself. The circuit design and components used in such circuits, such as voltage regulator modules (VRMs), on-chip package, pins, traces, vias, connectors etc., affect the impedance of the PDN and hence the quality of the power supplied is affected. Therefore, it is important to analyze whether power integrity problems are causing a reduction in signal quality.

Further, identifying problems associated with high-speed serial jitter requires understanding of both power and signal quality issues, since power rails and serial data exists on the same board designs. Thus, it is best to identify some power integrity issues, such as Power Supply Induced Jitter (PSIJ), early in the design stage of new circuits, such as at simulation stage, as board parasitics affect the final outcome of the circuit. Also, it is important to evaluate PSIJ at the system level, otherwise such problems may not be correctly identified as stemming from the power supply. PSIJ may be best detected on high-speed side, at the end of validation cycle. But making design changes only after PSIJ is detected at the end of the validation cycle is inefficient, because making such changes at such a late stage requires significant effort and re-work. And, as stated above, the negative effects of PSIJ on circuits that generate high-speed serial data increases as component density rates increase due to designs becoming more compact.

Present simulation models are complex, time-consuming, and do not provide guidance as to a source of noise expressed in high-speed serial (HSS) data. As such, there is no present simple solution available to measure and identify Power Supply Induced Jitter (PSIJ) occurring in HSS data.

Embodiments according to the disclosure address these and other deficiencies in the prior art.

### BRIEF DESCRIPTION OF THE DRAWINGS

FIG. 1 illustrates a power distribution network (PDN) and high-speed serial (HSS) board diagram on which test devices and methods according to embodiments of the present disclosure may operate.

FIG. 2 is a block diagram of a PDN that illustrates various sources of noise components affecting high-speed serial data that may be identified by test devices and methods according to embodiments of the present disclosure.

FIGS. 3A, 3B, 3C, 3D, 3E, 3F, 3G, 3H, 3I, 3J, and 3K are example screens presented to a user of a testing device to implement a wizard-style workflow process for measuring power supply induced jitter, according to embodiments of the present disclosure.

FIG. 4 is an example results screen that may be presented on a display of a test and measurement device that illustrates ripple frequency measurements, according to embodiments of the present disclosure.

FIG. 5 is an example results screen presented on a display of a test device that illustrates spectral plots of power rail spectral content as well as spectra for Time Interval Error (TIE), according to embodiments of the present disclosure.

FIG. 6A is an example screen presented on a display of a test device that illustrates an eye diagram and histogram of an HSS signal with PSIJ, according to embodiments of the present disclosure.

FIG. 6B is an example screen presented on a display of a test device that illustrates an eye diagram and histogram of an HSS signal after PSIJ removal, according to embodiments of the present disclosure.

FIG. 7A is an example screen presented on a display of a test device that illustrates eye diagrams and spectral plot displays both before and after removing PSIJ, according to embodiments of the present disclosure.

FIG. 7B is another example screen presented on a display of a test device that illustrates eye diagrams and spectral plot displays both before and after removing PSIJ, according to embodiments of the present disclosure.

FIG. 8 is an example data screen presented to the user for conveying results of the measurements produced by a measurement device, according to embodiments of the present disclosure.

FIGS. 9A, 9B, 9C, 9D, 9E, 9F, and 9G are example screens presented to a user of a testing device to implement a second, non-guided, type of workflow process for measuring power supply induced jitter, according to embodiments of the present disclosure.

FIG. 10 is an example flow diagram illustrating operations that may be used in measuring power supply induced jitter according to embodiments of the present disclosure.

FIG. 11 is a block diagram of an example test and measurement device for measuring qualities of a power supply and effects on a resultant circuit powered by the power supply according to embodiments of the disclosure.

It should be appreciated by those skilled in the art that any block diagrams herein represent conceptual views of illustrative methods embodying the principles of the present disclosure. Similarly, it will be appreciated that any flow charts, flow diagrams, and the like represent various processes which may be substantially represented in computer readable medium and so executed by a computer or processor, whether or not such computer or processor is explicitly shown.

### DESCRIPTION

Embodiments of the disclosure are directed to a method and apparatus for measuring power supply induced jitter (PSIJ) occurring in high-speed serial (HSS) data, and furthermore to providing tools to a user to determine whether such jitter is related to noise in a power supply.

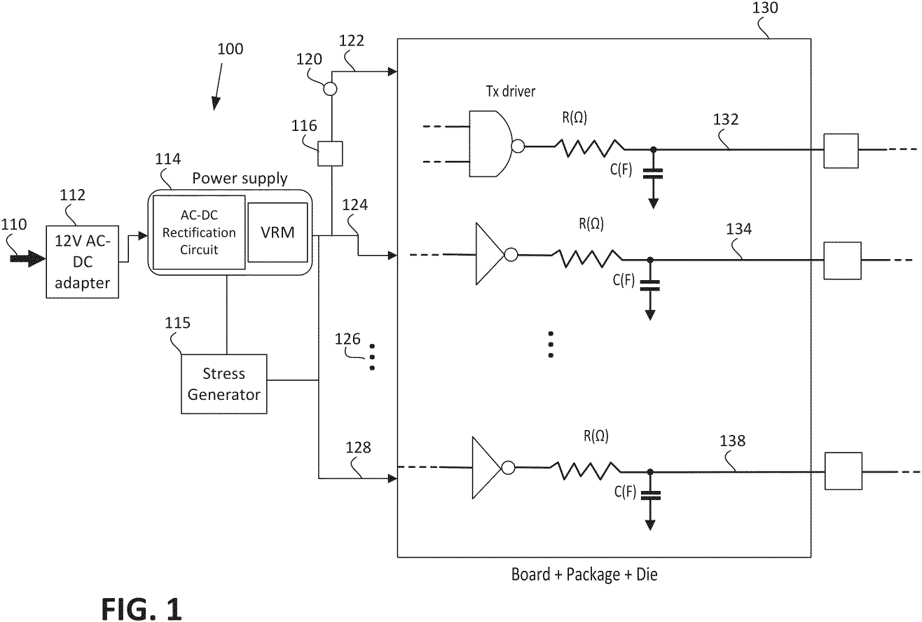

FIG. 1 is a block diagram illustrating an example power distribution network (PDN) 100 and a high-speed serial (HSS) board 130 on which test devices and methods according to embodiments of the present disclosure may operate. The power distribution network 100 may include various components, such as an AC-DC adaptor 112, which is fed from a supplied voltage 110. The supplied voltage may be, for example, between 8 - 25 Volts. The supplied voltage passes from the adapter 112 to a power supply 114, which itself may include, for example, an AC-DC rectifier as well as a voltage regulator module (VRM). Further components of the power distribution network 100 may include a buck converter 116 for stepping down voltage from the power supply 114, as well as a power rail probe access 120 for measuring qualities of the power distribution network. These components of the power distribution network 100 operate together to produce power for the various power rails supplied to a board, package, or die. And any of above-described components, or others, of the power distribution network 100 may be a source of noise that may affect data generated by components powered by the power distribution network.

In the illustrated embodiment, the power produced by the power distribution network 100 is provided to a board 130 that includes circuits for producing High Speed Serial (HSS) Data. Typically there are more than one power rails supplied to a board, package, or die, for a variety of reasons. Some power rails carry different voltages, and thus must be separated from one another. Other power rails are separated to route power to components with a minimum of interference. For example, rather than routing a power rail past a particularly noisy component, the power could instead be split, with a first power rail supplying power to components before the noisy component, and another power rail supplying power to components after the noisy component. In FIG. 1, there are multiple power rail outputs for the board 130, a first power rail 122, a second power rail 124, and an nth power rail 128. An ellipsis 126 indicates that there may be any number of separate power rails supplied to the board 130 from the PDN 100. Interference or noise may be present on any component of the power distribution network 100, which may further be transmitted to other circuits having a common board, package, or die. Noise from the PDN 100 may exhibit itself as ripple and/or voltage drift, which, as described below, may be measured by a measurement instrument. Spectral analysis of the power supply signal from the PDN 100 may be employed to determine if noise from the PDN occurs at particular frequencies. Also, some embodiments of the disclosure include a stress generator 115, which may be used to inject a repeating signal at a particular frequency into the PDN 100 to artificially stress the PDN. Effects of the artificial stress on the PDN 100 may be measured by the measurement instrument to help determine a causal link between noise on the PDN 100 and noise on data-generating circuits powered by the PDN 100. The stress generator 115 may include a function generator or other signal source to apply a repeating waveform to the PDN 100. The waveform may be in the form of a ripple, such as a sine wave, or may include other shaped waveforms as well, such as triangular, saw-tooth, or square-waves. In some embodiments the user may specify a frequency at which the repeating waveform is applied. Further, although the stress generator 115 is illustrated as applying the ripple, or other stress, to the power supply 114 and to the power rails, the stress generator 115 could be coupled to any component in the PDN 100 to generate stress. The stress generator 115 is not necessarily used in all embodiments, and instead noise or ripple that is naturally present on the PDN 100 may be measured and evaluated, as described below.

Illustrated on the board 130 are three separate circuits 132, 134, 138, that may be affected by noise or disturbances from either the power supply 100, or even operation from a neighboring circuit. Noise in a particular circuit may come from a number of different sources. A first type of noise may be natively present in a particular circuit, which is referred to as self-aggression noise. A second type of noise is caused when one circuit transfers noise to another circuit. Generally the noise-producing element is referred to as an aggressor while the other circuit is referred to as a victim circuit. A third type of noise is when two circuits affect each other, which is sometimes called mutual aggression noise. Mutual aggression noise may be expressed as crosstalk noise between the two circuits. Noise coupled onto packages and interconnects, such as noise sourced from a power distribution network, is yet another type of noise that often affects HSS circuits. Embodiments of the disclosure provide tools and methods of identifying the source of power supply noise present in HSS signals coupled to the power supply.

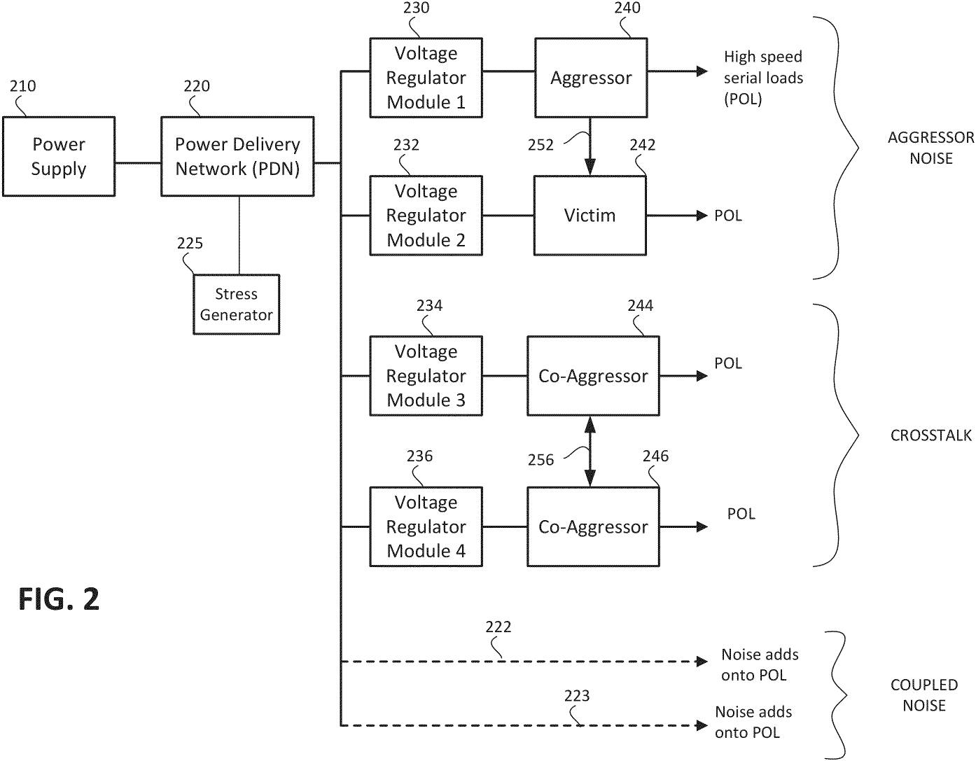

FIG. 2 is a block diagram of another power distribution network that illustrates various sources of noise components affecting high-speed serial data that may be identified by test devices and methods according to embodiments of the present disclosure.

FIG. 2 illustrates typical sources of noise components of the power supply affecting high-speed serial (HSS) data. A power supply 210 generates power for a power delivery network 220. In FIG. 2, the power delivery network 220 is coupled to four different regulator modules, 230, 232, 234, and 236, which may generate different voltages for various circuits powered by the power delivery network. As in FIG. 1, a stress generator 225 may be used, in some embodiments, to inject ripple or other noise into the PDN 220 to assist correlation analysis with jitter on data-generating circuits, as described below. In FIG. 2, an aggressor circuit 240 is a noisy circuit that transfers noise from itself to a victim circuit 242. The noise is represented as reference 252. The output of both the aggressor 240 and victim 242 are high speed serial loads, referred to as Point of Load (POLs). So, noise within the aggressor circuit 240 may have its source in the aggressor circuit itself, or in the voltage regulator module 230. In any case, in this example, noise from the aggressor circuit 240 is transferred to the victim circuit 242, where it may be expressed as noise on the POL from the victim circuit 242.

A related form of noise transfer is when two circuits mutually affect each other, which is illustrated as noise 256 transferred between two co-aggressor circuits 244, 246. Sometimes this mutual aggressor noise is referred to as crosstalk, which may be expressed on the POLs from both co-aggressors 244, 246.

A third form of noise is illustrated emanating from power rails 222, 223, which are additional power rails sourced by the power delivery network 220. These power rails 222, 223 are noisy by virtue of being coupled to other noisy rails in the power delivery network 220. The source of such coupled noise may be difficult to detect, because it may be generated by any of the components illustrated in FIG. 2.

The present disclosure describes a test and measurement device that, among other features, includes different types of workflow processes for enabling a user/design engineer to identify noise, such as Power Supply Induced Jitter (PSIJ) in a high-speed serial data (HSS) circuit coupled to the power supply. These workflow processes can include a wizard-style workflow, which guides the user through the testing, or may be a non-guided menu workflow. Both types of workflow utilize a graphical user interface (GUI) on a measurement instrument to help the user measure jitter or other noise on high-speed data and determine whether it stems from power supply rail noise. Although the below description is given primarily with reference to identifying Jitter in the HSS data, embodiments of the disclosure may also identify other defects in the generated data, such as vertical noise, phase noise, or other defects, which may be correlated to noise from the power delivery network.

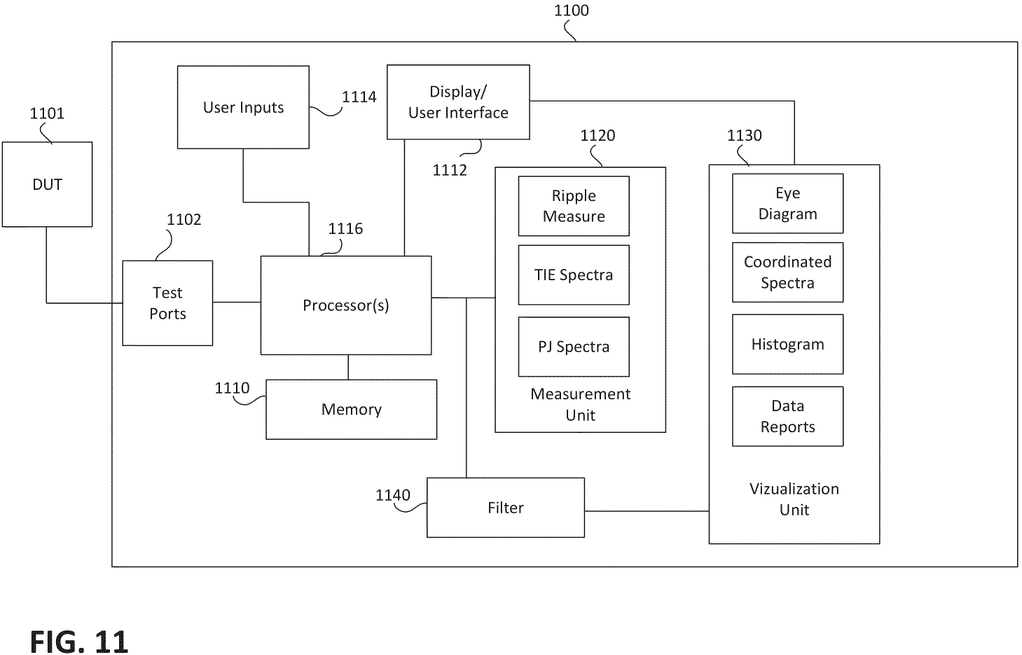

In general, a measurement instrument for identifying PSIJ includes one or more inputs, or channels, for accepting signals to be measured or tested from a Device Under Test (DUT). An example instrument is described with reference to FIG. 11 below. In the present example, the DUT is a device that generates high-speed serial data. An operator configures the measurement instrument to measure parameters of the input signal to be tested. In this present example, the operator configures the instrument to determine whether power supply noise, such as ripple, voltage drift, or other detectible artifact, is contributing to noise on the high-speed serial data. In some embodiments the operator may program the measurement instrument using programming commands. In other embodiments, described below, the operator uses a GUI on a display screen of the measurement instrument to perform the setup and guide the testing of the DUT that generates the HSS data, so that the user can readily determine whether noise on the HSS data stems from the power supply.

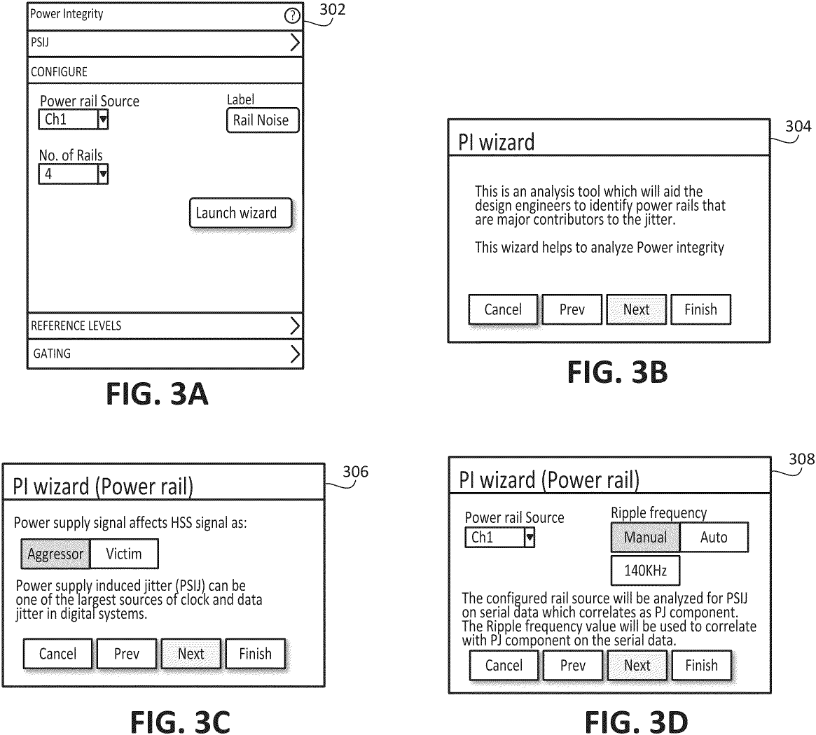

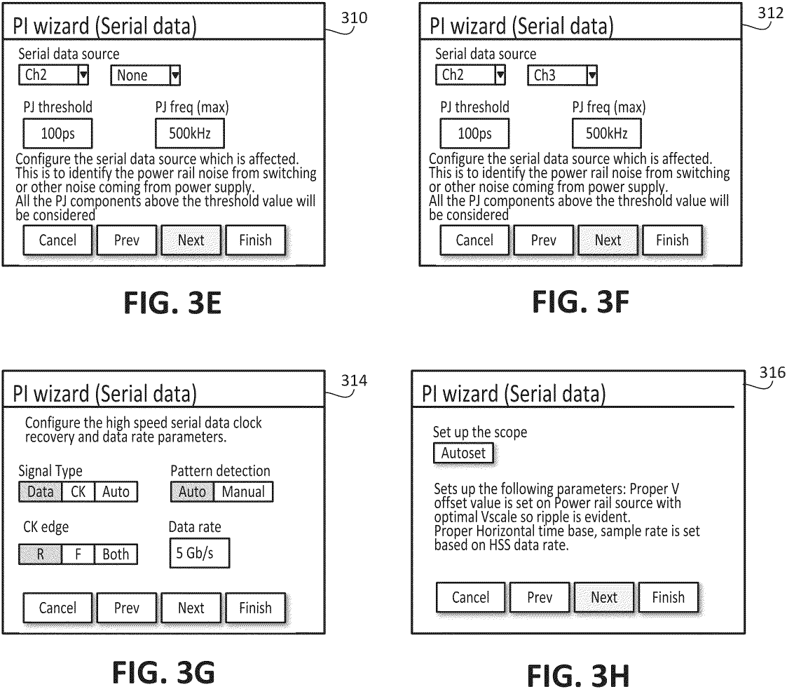

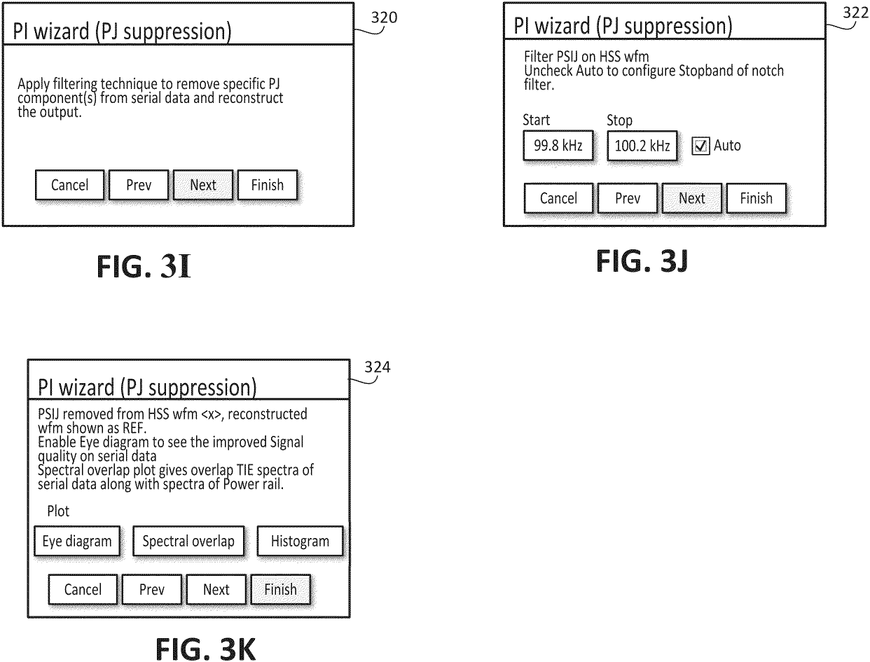

FIG. 3A illustrates a first screen, or menu 302, in a wizard-style process flow presented to a user or operator of a test and measurement device. In this example, the measurement device is coupled to a DUT that includes one or more power rails as well as one or more HSS data generators for testing. In a first window of the menu 302, the operator selects a power integrity (PI) test configuration. In the PI configuration, the operator then selects a particular power rail source channel to be measured and enters the total number of power rails in the DUT. In the illustrated example the tested power rail is on channel 1, and there are 4 power rails. The operator may label the test in a labeling window within the menu 302. Once the configuration using menu 302 is complete, the user can select the launch wizard button to start the wizard-style process flow described below.

FIG. 3B shows a launched PI wizard window 304 which aids the user to analyze power integrity. The launched PI wizard is followed by PI wizard power rail configuration menu 306, as illustrated in FIG. 3C. In the PI wizard power rail configuration menu 306, the user defines the type of power supply, such as specifying whether the power supply signal affects HSS signal as aggressor or as victim. In the illustrated embodiment, the user has defined that the power supply signal affects the HSS signal as an aggressor.

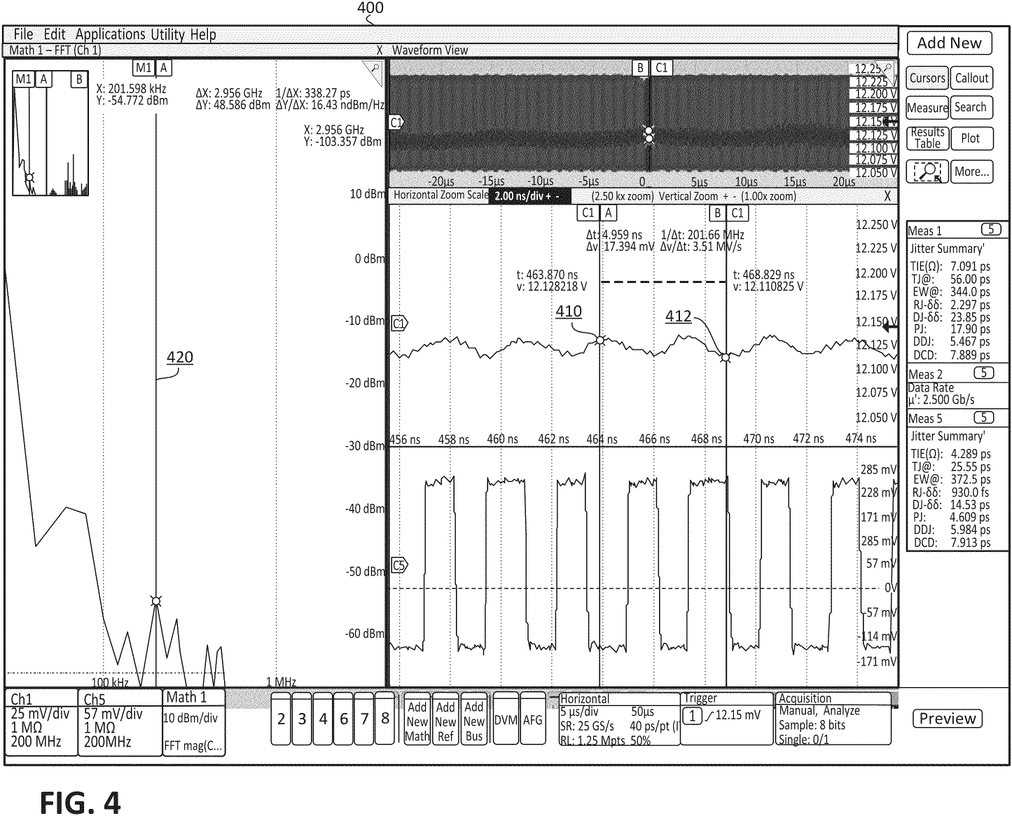

A power rail configuration menu 308, illustrated in FIG. 3D, allows the user to select the power rail source channel and configure a ripple frequency for artificial, periodic, noise applied to the power rail. This applied noise may be identifiable in other components of the DUT by the measurement instrument, which helps determine a source of noisy components in the DUT that may affect overall performance. Specifically, the HSS data generated by the circuit may also be analyzed to determine if the noise applied to the power supply is found in the HSS data. Applying periodic noise to the power rail generates aberrations in the power distribution system, which may be tested by the user to determine if PJ in the HSS data was caused by the power distribution system. In some embodiments, no external noise or ripple is applied to the power supply during testing, and instead noise that is naturally present on the power distribution network is sufficient for analysis. In either case, the above workflow processes allow the user to test for a correlation between significant noise frequencies in the configured power rail, and HSS data. Referring back to the menu 308 of FIG. 3D, the selected power rail channel is configured for analyzing the PSIJ on the HSS data. The ripple frequency of the power rail may be configured automatically or manually. In manual mode, the user measures a frequency of noise, such as ripple, of the power rail source coupled to the selected input channel of the measurement instrument. If the ripple is significant on the measured DC voltage, then it appears to the measurement instrument as an AC component, as shown in FIG. 4, which illustrates an example measurement screen 400 shown on the measurement instrument. The user can manually measure this frequency using, for example, oscilloscope cursors 410, 412. Another process to measure the ripple frequency is to turn on MATH FFT on the power rail source channel and identify the dominant frequency after fundamental component, as highlighted in FIG. 4 with plot cursor 420. This measured value can be entered in the menu 308 (FIG. 3D) as the ripple frequency in the manual mode. In one embodiment, the identification of the dominant frequency using MATH FFT can be automated. Alternately, the user may enter the frequency value for the value in menu 308 in the manual configuration by selecting a frequency value from a data sheet describing the DUT that includes the HSS data generator.

After the user has configured the power rail using menus 302-308, next the user configures the HSS data testing parameters using menus 310, 312, 314, and 316, illustrated in FIGS. 3E, 3F, 3G, and 3H, respectively. These menus 310-316 are still part of the wizard flow to help the user automate testing on a test and measurement device. In menu 310, the source channel on which serial data may be affected by noise on the power supply is selected. In the illustrated embodiment, the HSS data is received on channel 2 of the measurement instrument. This testing of the HSS data source helps the user identify whether noise from the power rail is caused by switching, or if there is another source originating from the power supply. Further, in the serial data configuration menu 310, the user may enter a PJ threshold, in terms of a time period, and a maximum frequency for periodic jitter. This PJ configuration allows the measurement instrument to consider all of the PJ components longer than the PJ threshold time period and equal to or below the maximum PJ frequency value. In one embodiment, specifying the upper frequency limit for the power rail PJ frequencies as well as the time threshold value of the PJ helps identify whether power rail noise is coming from switching, or originating from the from power supply. Typically, the maximum PJ frequency limit depends on the knowledge of switching frequencies of regulators used in the design. In one embodiment, the upper limit of the PJ frequency may be less than 10 MHz.

Although the menu 310 only identifies a single HSS data source, i.e., channel 2, embodiments of the disclosure may specify two HSS data sources, such as illustrated in menu 312 of FIG. 3F. If the user is configuring a measurement instrument to have a single HSS source, then the user can set the second serial data source window in the menu as ‘none’, as illustrated in menu 310. In this single source measurement, the measurement instrument utilizes full bandwidth (BW) testing. When two sources are used for measurement, such as in menu 312, the instrument computes a MATH differential waveform as a difference of the two specified sources.

Next in the wizard-style flow described in FIGS. 3A – 3K, a menu 314 prompts the user to configure clock recovery information for the clock that drives the high-speed serial data as illustrated in FIG. 3G. Specifically, the user enters information about a signal type, pattern detection, clock edge, and data rate, as illustrated in menu 314 of FIG. 3G. The signal type may be data, clock, or auto. The pattern detection may be automatic or manually detected. The user may specify a rising edge, falling edge, or both rising and falling edges of the clock be detected. A data rate, such as 5Gb/s is also specified by the user in the menu 314. Typically a Constant Clock Recovery (CCR) method is recommended, so that a measured Time Interval Error (TIE), which is a measurement of the difference in time between an observed clock edge and its expected edge, includes all of the components to measure periodic jitter.

After the clock recovery information is entered in menu 314, the user can press the autoset button in a menu 316 (FIG. 3H) to automatically set up the measurement instrument for measuring voltage ripple on the selected power rail or rails, referred to as PS Ripple, and for measuring TIE on the selected HSS data channels. Specifically, pressing the autoset button in the menu 316 sets up parameters on the measurement instrument, such as an oscilloscope, based on the user input for power supply and HSS configurations. For example, setup parameters include a voltage offset value on power rail source with an optimal Vscale, so ripple is evident. A horizontal time base is also set, with a sample rate based on HSS data rate that was entered in menu 314. Triggers are also automatically set in the instrument that are sourced to the HSS waveform.

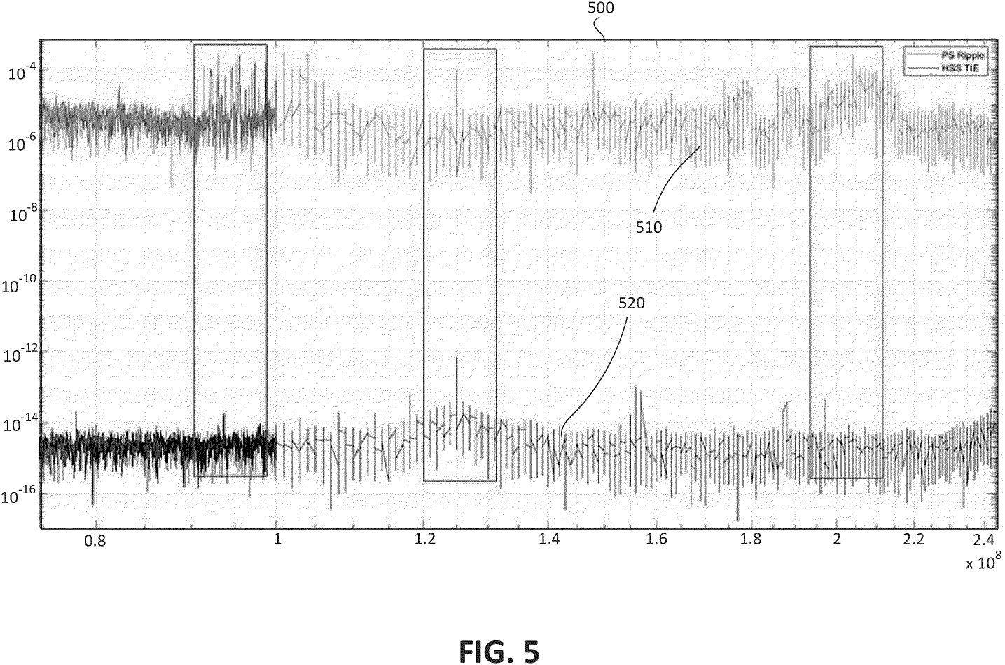

FIG. 5 illustrates an example display 500 of the measurement instrument after being set up through menu 316 and making an initial set of measurements. The display 500 may be shown on a main display of the measurement instrument or presented on a remote display. In general, a spectral plot display 510 of the PS Ripple measurements of the selected power rail or rails are presented in a top portion of the display 500, while a spectral plot display 520 of the TIE measurement of the selected HSS data is presented in the lower portion of the display 500. The two measurements are correlated by mapping the measurements over the same frequency span. In other words, the TIE spectra 520 are overlapped on to power supply spectra 510. This correlated display lets the user visually correlate overlapping dominant power components showing as jitter components on the serial data. In one embodiment, the spectral overlay plot has the flexibility to zoom, and also allows the user to set the horizontal axis range, resulting in better visuals. This spectral representation includes all the PJ components and harmonics, and allows the user to analyze and capture the jitter present in the power supply. In the overlapped spectra, such as illustrated in the output 500 of FIG. 5, all of the PS and TIE correlating components at the same frequencies are recorded and displayed for the user. Although the display 520 shows the TIE of the HSS data, other characteristics of the HSS data signal may be measured and shown, such as other forms of jitter, as well as vertical noise, and/or phase noise, for example.

Embodiments of the disclosure include an ability for the wizard-based flow to automatically suggest methods and specific parameters to reduce or minimize the periodic jitter measured by the instrument in the preceding steps. As illustrated in a menu 320 of FIG. 3I, the wizard-based flow allows the user to apply a filter, or filtering technique, to remove specific PJ components from the serial data, and to reconstruct the HSS data output after having the filter applied. In a menu 322 of FIG. 3J, the wizard-based flow automatically determines parameters of a notch filter to apply to the HSS data, so that the user can visualize what the data would look like if the power supplied by the power distribution network would have low noise levels. Or, also as illustrated in the menu 322, by unchecking an ‘auto’ box, the user may enter particular start and stop frequencies so that an appropriate notch filter matching the entered frequencies can be applied by the instrument to the HSS data. This gives the user a strong tool for effective circuit design of HSS data circuits, which effectively removes the PSIJ from the HSS data waveform, and then reconstructs the HSS data waveform for viewing by the user. A final menu 324 of the wizard-based flow appears in FIG. 3K, where the instrument provides a choice to the user whether to view the results of the reconstructed HSS data, after having had the notch filter applied, in either an eye diagram, spectral overlap display, or a histogram.

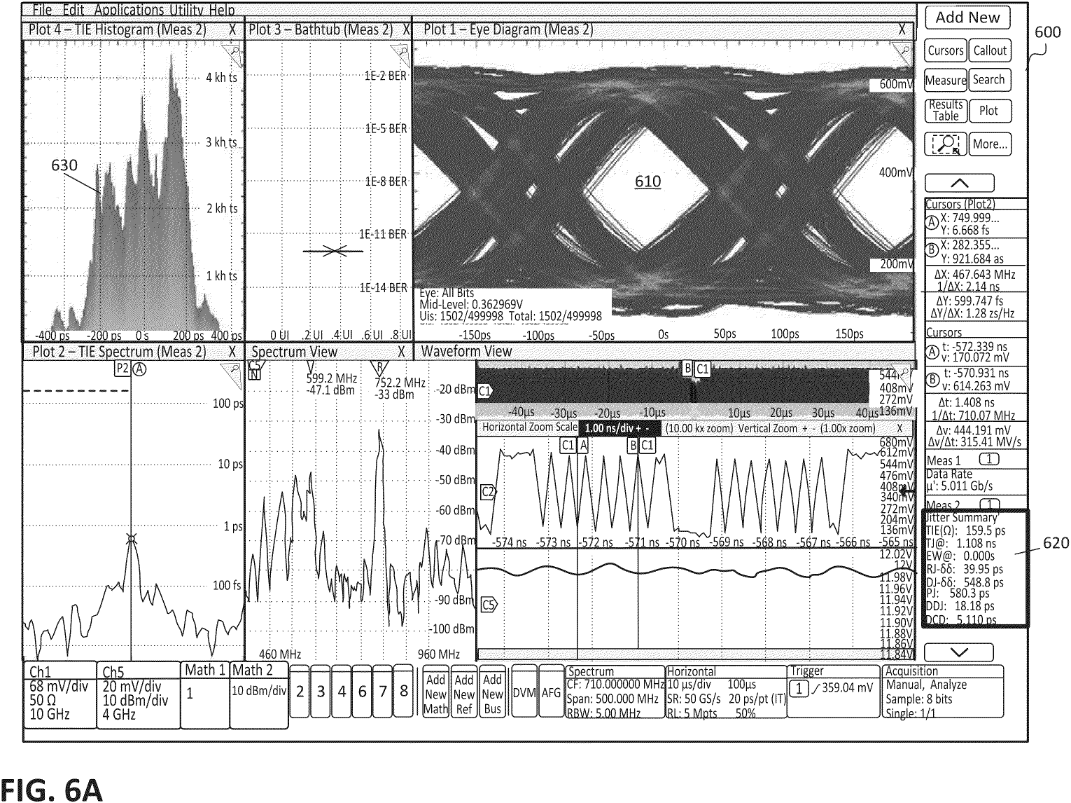

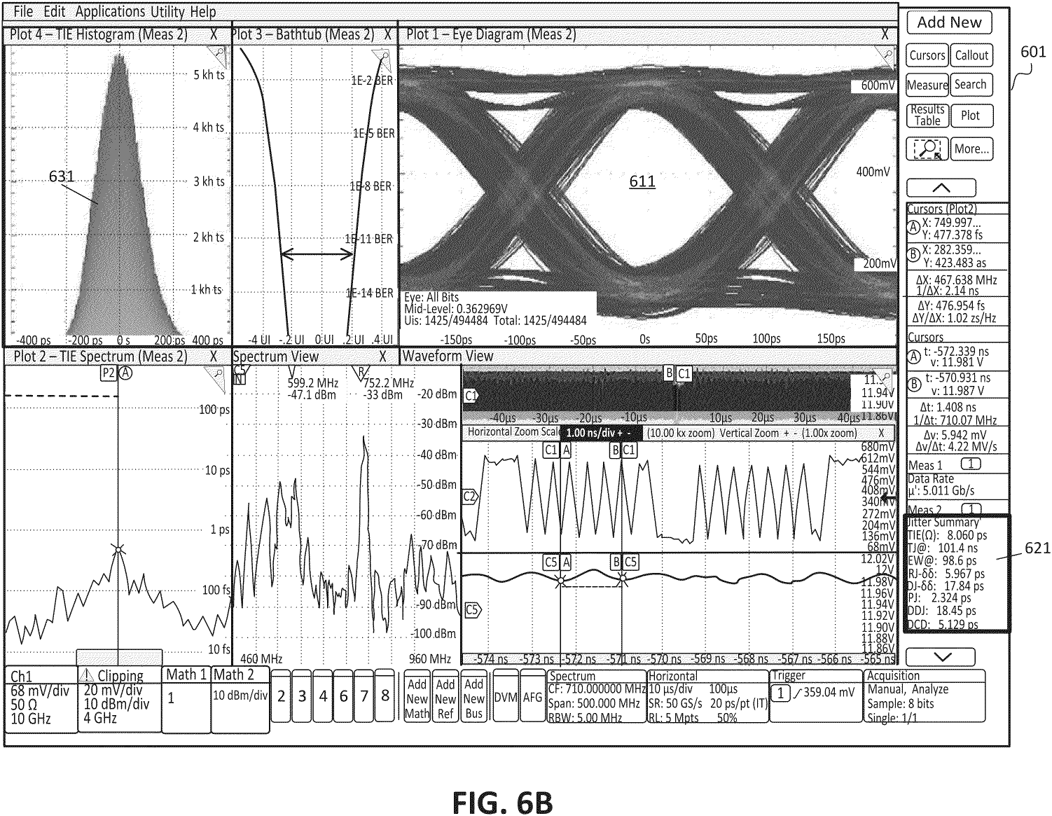

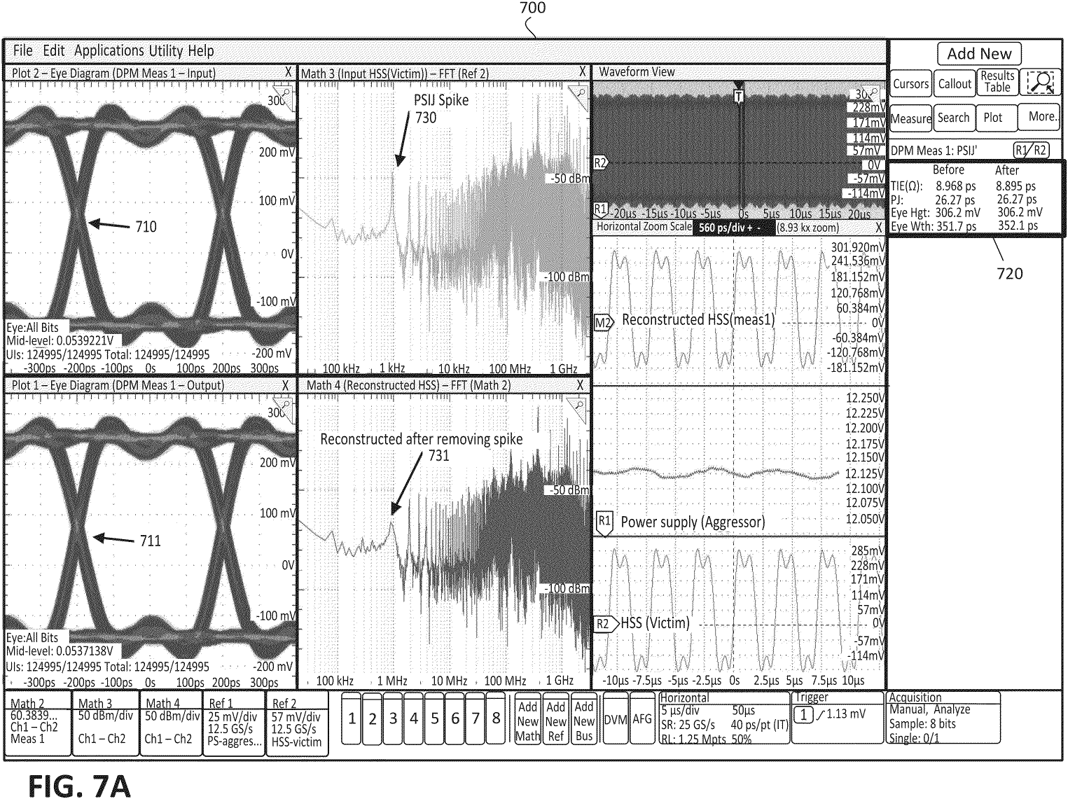

Example eye diagrams illustrating increased margin are illustrated in FIGS. 6A and 6B. Specifically, a display screen 600 of FIG. 6A, which may be an example output display of the measurement device used to measure the PSIJ, described above, includes an eye diagram having an opening 610. The eye diagram on the display screen 600 is an eye diagram of the HSS data prior to having any notch filter applied. After the notch filter is applied to the HSS data, as described above, a new eye diagram is illustrated on the display screen 601 of FIG. 6B, having an opening 611. As seen by inspection, the eye opening 611 in the eye diagram of FIG. 6B is larger than the eye opening 610 in the eye diagram of FIG. 6A. The increase in the opening size between the eye diagrams of FIGS. 6A and 6B is due to the application of the notch filter in the HSS data, as described above. Specifically, the eye diagram of FIG. 6A is the diagram of the base HSS data without any filtering, while the eye diagram of FIG. 6B is the diagram of the base HSS data after the notch filter has been applied. Applying the notch filter improves the quality of the HSS data signal by removing or reducing PSIJ caused by the power supply. In addition to viewing the changes in eye diagrams between FIGS. 6A and 6B, jitter measurement data measured by the instrument may also be displayed in measurement display blocks 620, 621, illustrated on the lower right-hand side of the displays 600, 601.

TIE histograms are also illustrated as windows in the example screens 600, 601 in FIGS. 6A and 6B, respectively. Specifically, the window in the upper-left corner of each example screen 600, 601 generates a histogram of TIE taken from the HSS data before (FIG. 6A) and after (FIG. 6B) the notch filter was applied. More particularly, a TIE histogram 630 of FIG. 6A exhibits many different data spikes, which are indicative of the harmonics of ripple applied to the power rail. Note how the ripple appears in the TIE of the HSS data, which means, in this design, noise on the power supply has a direct affect to the final HSS data. A TIE histogram 631 of FIG. 6A illustrates the TIE of the HSS data after the filter has been applied, which simulates removal of the PSIJ. Thus, a designer using these tools as described above is able to readily determine the connection between noise on a power rail and its resultant effects on the generated HSS data. By performing this analysis on preproduction designs, the designer may discover that a particular design is susceptible to aggressor noise, crosstalk, or coupled noise. Then the designer may make adjustments to harden the design against such noise sources.

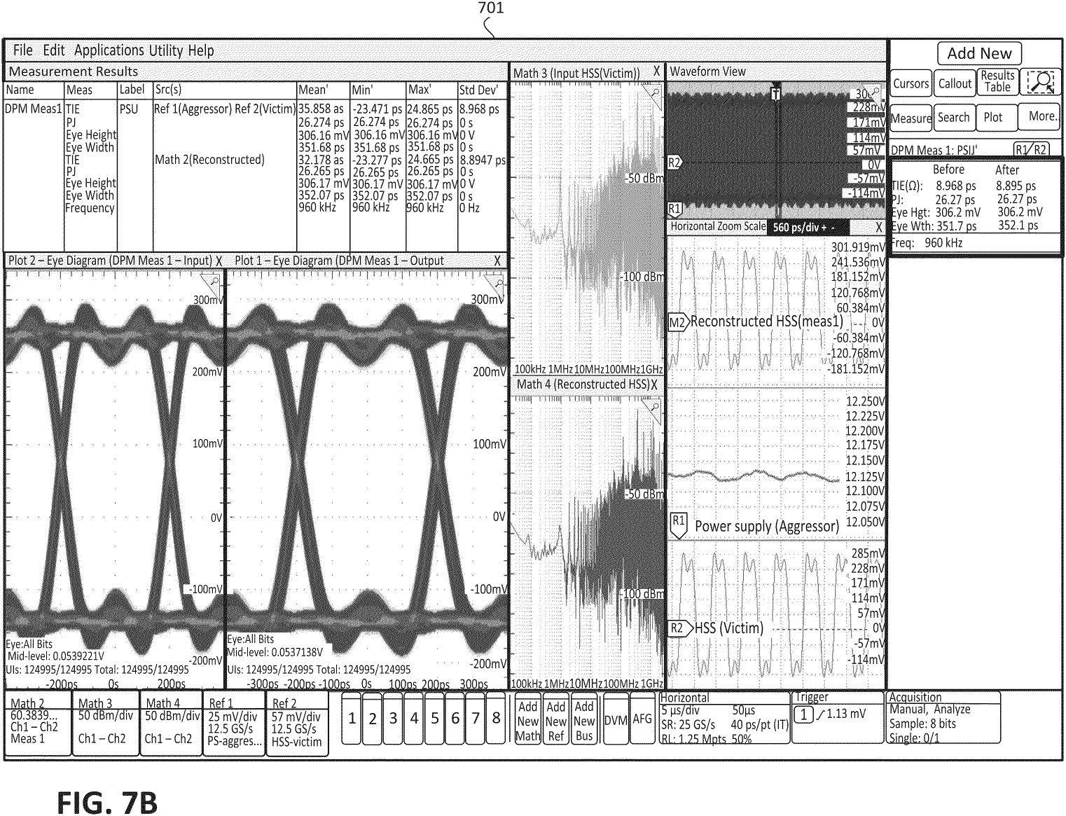

FIGS. 7A and 7B illustrate example display screens 700, 701, that may be also presented on a display of a test device according to embodiments to illustrate eye diagrams and spectral plot displays both before and after removing PSIJ. Display screen 700 of FIG. 7A includes two eye diagrams, on the left-most display windows. References 710 and 711 illustrate how the eye width is opened by applying the notch filter. Additionally, the display screen 700 illustrates a PSIJ spike 730 in a spectral view of HSS data, while reference 731 illustrates how applying the notch filter substantially reduces the spike. Similar to the displays 600, 601 of FIGS. 6A and 6B, display screen 700 includes a measurement display block 720 that shows measurement data both before and after application of the notch filter. FIG. 7B includes similar displays to that of FIG. 7A, but further shows how the user may customize the display to visualize measurement data using embodiments of the disclosure.

In one embodiment, the measurement instrument may calculate and show a percentage of eye opening improvement, which is known as margin improvement. This margin improvement analysis involves comparing the sizes of the eye openings before and after the filter has been applied, simulating PSIJ removal. The margin improvement may be displayed in a results badge that may be shown on a display screen. Specifically, an improvement in Eye Width (EW) and Eye Height (EH) may be determined as shown in Equations 1 and 2.

$$\text{Eye Width improvement} \left(\%\right) = \frac{\text{PJSuppressed EW}}{\text{OriginalEW}} * 100$$

$$\text{Eye Height improvement} \left(\%\right) = \frac{\text{PJSuppressed EH}}{\text{OriginalEH}} * 100$$

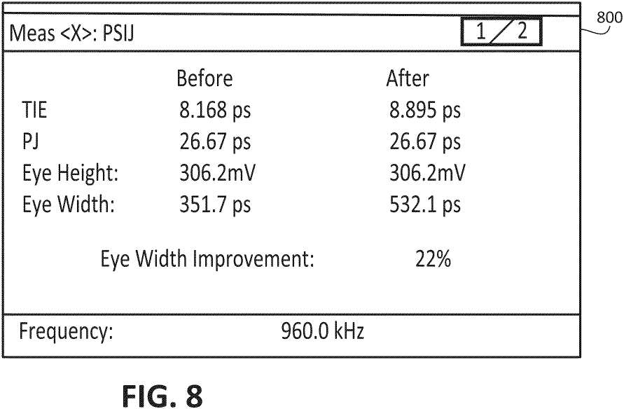

Either or both of the improvement percentages can be shown on the display of the measurement instrument, such as on a display screen 800, which is illustrated in FIG. 8.

As can be seen from above, using the wizard-style flow described with reference to FIGS. 3A - 3K, a user can be guided through the process of measuring PSIJ and determining how it affects the performance of an HSS data-generating device. Also, the wizard-style flow may automatically or allow the user to manually set parameters for various notch filters that, when applied to the HSS data waveform, simulate how the HSS data would appear without the PSIJ.

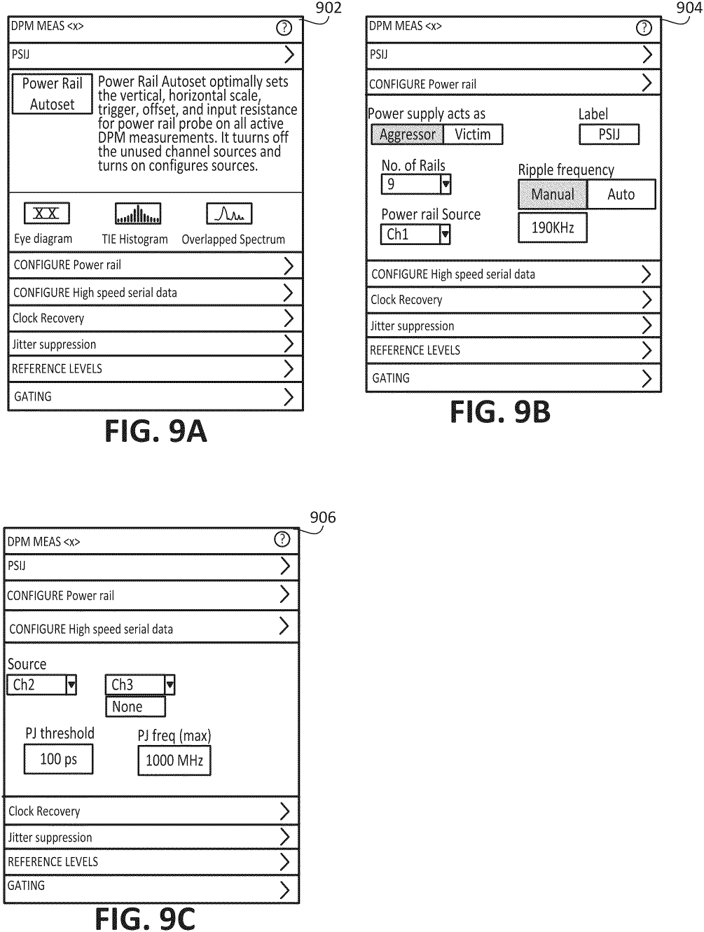

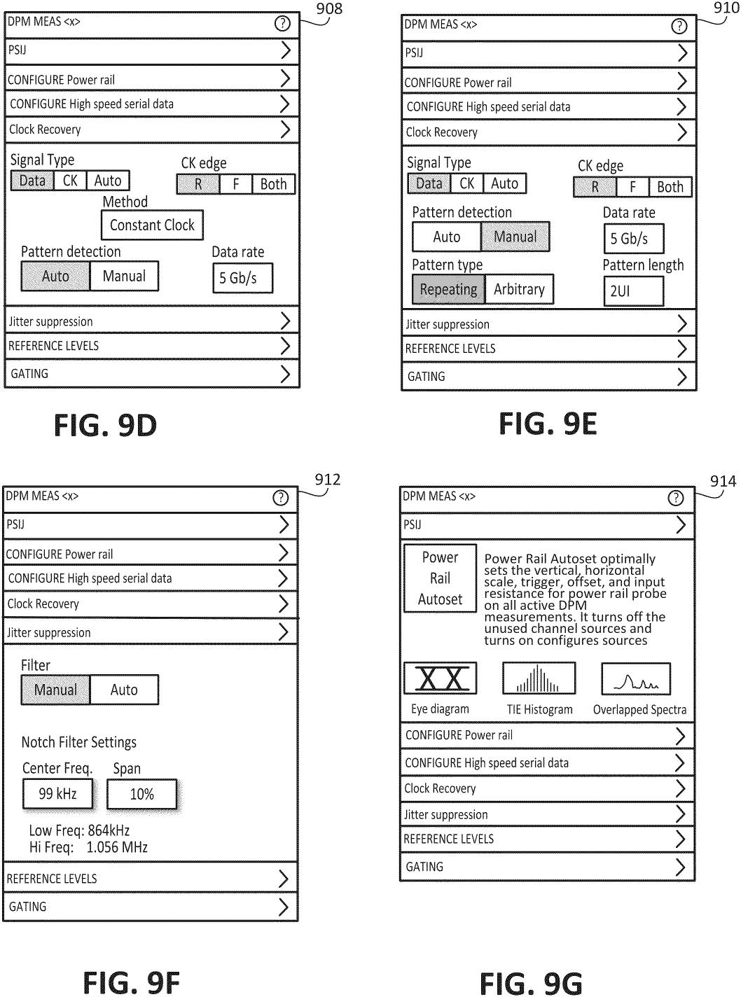

A new, non-guided menu workflow process for measuring the PSIJ of a HSS data generating circuit is illustrated in FIGS. 9A - 9G, which show various menus that may be presented on a display of a measurement instrument. The user interacts with the non-guided menus to set up and configure the measurement instrument to measure PSIJ, and to determine whether measured noise, in the form of TIE on the HSS data is correlated to the measured PSIJ. The non-guided workflow parallels and receives the same or similar information from the user as does the wizard-style workflow described above with reference to FIGS. 3A – 3K, but, in the non-guided workflow, the setup process is guided by the user rather than presented by the measurement instrument.

A menu 902 in FIG. 9A illustrates a power supply setup for measuring PSIJ, while menus 904 (FIG. 9B) illustrates a power rail configuration window where a user can configure the type of power supply, label, number of rails, ripple frequency and power rail source. FIG. 9C shows a menu 906 that allows the user to configure high-speed serial data source channels, as well as a PJ threshold value and a maximum PJ frequency. A menu 908, illustrated in FIG. 9D allows the user to configure clock recovery information, such as signal type configuration (data, clock, auto), clock edge (rising, falling, both), pattern detection (auto or manual), and specify a data rate of the HSS data. A menu 910 in FIG. 9E provides the user with an ability to specify a pattern type (repeating, arbitrary) as well as a patten length. Next, a menu 912 in FIG. 9F illustrates jitter suppression configuration, which, as described above, applies a filter to the HSS data. The menu 912 allows the user to configure filter parameters manually by entering a center frequency and frequency span, or the user can select automatic configuration. FIG. 9G illustrates the autoset configuration in a menu 914 for setting up the measurement instrument, such as an oscilloscope, for each PS and HSS channel. The menu 916 also allows the user to select an output of the analysis of the PSIJ and HSS data by selecting outputs using eye diagrams, overlapped (PS and TIE) spectra, or TIE histograms. Example eye diagrams were described above with reference to FIGS. 6A, 6B, 7A, and 7B. Overlapped PS and TIE spectra was described above with reference to FIG. 5.

In addition to the graphical expression of the measurements as illustrated in FIGS. 5-7, the non-guided workflow may also produce a result window, such as the window 800 of FIG. 8, to convey improvements in the measurement data directly to the user.

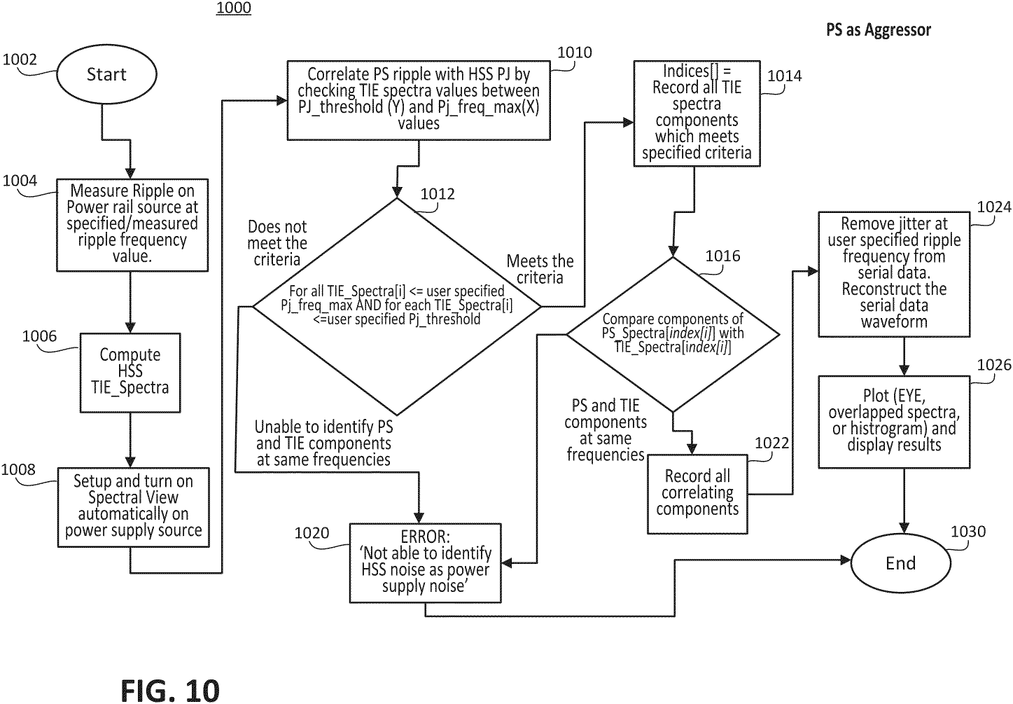

The above processes described in both the wizard-style workflow of FIGS. 3A - 3K and the non-guided workflow of FIGS. 9A - 9G, can be implemented through methods, such as those that incorporate example operations illustrated in FIG. 10.

In FIG. 10, an example process 1000 according to embodiments of the disclosure begins with initialization and setup of a measurement device, such as an oscilloscope, at an operation 1002. Example initialization operations include setting up power supply values and configuring one or more source channels to measure and identify PSIJ for the circuit design being tested. Another channel is set up to identify the source for the HSS data to be measured. Then, at an operation 1004, voltage ripple or other noise on the power rail source at the specified/measured ripple frequency is measured by the instrument and recorded as PS ripple. At an operation 1006, the instrument generates an HSS waveform from the HSS data input channel and then produces TIE spectra from the HSS waveform. An example of such TIE spectra is illustrated in the lower portion of FIG. 5. Next, a step 1008, the instrument generates a spectral view from the power supply source input channel, with center frequency set to the specified ripple frequency (PS_Spectra[]), which may have been specified or measured in the operation 1004. Next, operation 1010 correlates the power supply ripple measured in operation 1004 (PS ripple) to periodic jitter (PJ) determined from the HSS TIE measurement by checking the HSS TIE spectra values between Pj threshold (Pj_threshold (Y)) and maximum Pj frequency (Pj_freq_max(X)) values. Then, the process 1000 continues to operation 1012, which is a comparison to determine whether the same frequencies of noise in the power supply components are also sensed in the HSS data. If so, then the overall circuit design is susceptible to noise on the power supply carrying through to the final HSS data output. If there is not much of a correlation between sensed frequencies on the power supply with the final HSS data output, then the overall circuit design is less susceptible to noise on the power supply affecting HSS data output. More specifically, the comparison in operation 1012 evaluates the TIE spectra for the user-specified maximum Pj threshold and PJ threshold frequency. The operation 1012 includes two separate criteria. The first criterion of operation 1012 is met when all of the TIE spectra recorded by the measurement device in the present test is less than or equal to the maximum PJ frequency that the user specified in operation 1004. The second criterion of operation 1012 is met when each of the TIE spectra recorded by the measurement device is less than or equal to the user-specified Pj threshold value. If both criteria of operation 1012 are met, then the process 1000 continues to an operation 1014, where the process 1000 records all the TIE spectra components that meet the criteria specified in operation 1012. If instead either of the criteria of operation 1012 are not met, then the process 1000 continues to an operation 1020 where the user is informed with a display, such as “Error ‘Not able to identify valid power supply noise’”. In other words, if the process 1000 reaches operation 1020, the process determined that no noise (or not a significant enough amount of noise) sensed in the HSS data could be traced back to noise coming from the power supply using the test outlined in the operation 1012.

Referring back to operation 1014, in this operation, all the TIE spectra components of the present test that meet the specified criteria in operation 1012 are recorded. Then, an operation 1016 compares the PS spectral frequency (PS_spectra[]) recorded in operation 1014 to the TIE spectral frequency recorded in the operation 1006 (TIE_spectra[]). If there is commonality at the same frequencies for these PS and TIE components, then all of the correlating components are recorded at an operation 1022. And, if none of the PS and TIE components have common frequencies, then the process 1000 proceeds back to operation 1020, where an error or other explanatory message is provided to the user. When the process 1000 reaches operation 1020, i.e., when noise, such as jitter, on the power rail is not found in the HSS data at any common frequencies, the process 1000 terminates at an operation 1030. If instead noise, such as jitter, on the power rail is found to be correlated with noise found on HSS data, the process 1000 generates a new HSS data signal of what the HSS data would look like if the noise were removed. Specifically, when noise on the power rail is found in the HSS data, the instrument applies a filter, such as a notch filter, to the ripple frequency, and reconstructs the HSS data waveform in an operation 1024. Then, an operation 1026 plots this reconstructed HSS data waveform on an output display of the measurement instrument, or elsewhere, to show the user how the HSS data is improved with application of the notch filter. As described above, these results may be shown to the user in an eye display or histogram (both described above with reference to FIGS. 6A, 6B, 7A, and 7B), or overlapped spectra (described above with reference to FIG. 5). In addition, results of such improvement may be shown to the user in a data display, such as illustrated in FIG. 8.

As described above, when the measurement instrument determines that PS spectra generated by the instrument from the power supply and TIE spectra components generated by the instrument from the HSS data occur at the same frequencies, this indicates that jitter is due to power rail noise. Although TIE spectra values are described in the above examples for analyzing the HSS data, embodiments of the disclosure may use other types of jitter or noise values in the correlation analysis. Using embodiments of this disclosure, the design engineer can modify a circuit design to minimize the correlation. Further, embodiments of the disclosure provide an ability to quantify circuit improvement by generating an eye diagram of the output data signal. This eye diagram shows how the clean simulation will look once the jitter is removed from the designed circuit. Thereby, the proposed solution will result in designing an improved high speed serial system.

One of the advantages of the proposed method and apparatus is that a design engineer can modify a power distribution network design to reduce power supply induced jitter from the circuit at the very early stage. Another advantage is that the design engineer will have insight and hence confidence before making PI side hardware design changes during their initial phase of their prototypes.

FIG. 11 is a block diagram of an example test and measurement instrument 1100, such as an oscilloscope, for implementing embodiments of the disclosure as disclosed herein. The measurement instrument 1100 may be an example of the measurement instrument described above. The test and measurement instrument 1100 includes one or more test ports 1102, which may be any electrical signaling medium. Test ports 1102 may include receivers, transmitters, and/or transceivers. Test ports 1102 are used to receive signals from an attached device, such as a DUT 1101, a circuit, a discrete device or set of devices, or other object being tested. In some embodiments the DUT 1101 is a HSS data-generating device with its power rails as well as HSS data coupled to the test ports 1102. Each input port 1102 may represent a channel of the test and measurement instrument 1100. As described above, one or more power rails from the DUT 1101 may be coupled to the instrument 1100 through one or more channels, and one or more HSS data outputs may be coupled to the instrument 1100 through other channels. The instrument may receive these multiple channels for testing in parallel, i.e., at the same time. The input ports 1102 are coupled with one or more processors 1116 to process the signals and/or waveforms received at the ports 1102 from one or more devices under test 1101. Although only one processor 1116 is shown in FIG. 11 for ease of illustration, as will be understood by one skilled in the art, that multiple processors 1116 of varying types may be used in combination, rather than a single processor 1116.

The input ports 1102 and one or more processors 1160 can also be connected to a measurement unit 1120 within the test instrument 1100. The measurement unit 1120 may include individual functions to perform the measurement and correlation operations described above. For instance, the measurement unit 1120 can include any component or operation capable of measuring aspects of a signal received via the input ports 1102 in either or both of the time and frequency domains. For example, the measurement unit may include functions or processes for measuring ripple, for creating TIE spectra from received HSS data, and for creating spectra from PJ data as described above. Once these measurement functions are complete, the one or more processors 1116 may coordinate and evaluate these measurement functions for measurements made from the DUT 1101.

A visualization unit 1130 assembles various displays generated from measurements and analysis made by the measurement unit 1120 and sends them to a display 1112 for showing on the instrument 1100. In some cases the display may be remote from the instrument 1100 itself. Visualizations may include displays such as eye diagrams, one or more spectra, including spectra from two or more measurements that are aligned across the same frequency range, histograms, and data reports that may present measurement data in numerical form. Each of these visualization types are described in detail and illustrated above.

Further, a filtering function 1140 may also operate as described above, where the filtering function applies a filter for specific waveforms at particular frequencies. Also as described above, this filtering has the effect of simulating a result of reducing the effect that certain components may have on each other, such as noise on a power rail affecting HSS data.

The test and measurement instrument 1100 may include additional hardware and/or processors, such as conditioning circuits, analog to digital converters, and/or other circuitry to convert a received signal to a waveform for further analysis. The resulting waveform can then be stored in a memory 1110, as well as displayed on a display 1112.

The one or more processors 1116 may be configured to execute instructions from the memory 1110 and may perform any methods and/or associated steps indicated by such instructions, such as displaying values measured to a coupled device according embodiments of the disclosure. The one or more processors 1116 may perform the functions described above with reference to the measurement unit 1120, the visualization unit 1130, or the filter 1140, or the one or more processors 1116 may work in conjunction with yet other processors to perform such functions. Memory 1110 may be implemented as processor cache, random access memory (RAM), read only memory (ROM), solid state memory, hard disk drive(s), or any other memory type. Memory 1110 acts as a medium for storing data, computer program products, and other instructions.

User inputs 1114 are coupled to the one or more processors 1116. User inputs 1114 may include a keyboard, mouse, trackball, touchscreen, and/or any other controls employable by a user with a User Interface on the display 1112. The user interface of the display 1112 may present the wizard-style workflow or the non-guided workflow, both described above, to the user. The display 1112 may be a digital screen, a cathode ray tube- based display, or any other monitor to display waveforms, measurements, and other data to a user. While the components of test instrument 1100 are depicted as being integrated within test and measurement instrument 1100, it will be appreciated by a person of ordinary skill in the art that any of these components can be external to test instrument 1100 and can be coupled to test instrument 1100 in any conventional manner (e.g., wired and/or wireless communication media and/or mechanisms). For example, in some embodiments, the display 1112 may be remote from the test and measurement instrument 1100.

Aspects of the disclosure may operate on particularly created hardware, firmware, digital signal processors, or on a specially programmed computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a computer readable storage medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The foregoing description of the invention has been set merely to illustrate the invention and is not intended to be limiting. Since modifications of the disclosed embodiments incorporating the substance of the invention may occur to person skilled in the art, the invention should be construed to include everything within the scope of the invention.

In the following description, for purpose of explanation, specific details are set forth in order to provide an understanding of the present disclosure. It will be apparent, however, to one skilled in the art that the present disclosure may be practiced without these details. One skilled in the art will recognize that embodiments of the present disclosure, some of which are described below, may be incorporated into a number of systems.

However, the systems and methods are not limited to the specific embodiments described herein. Further, structures and devices shown in the figures are illustrative of exemplary embodiments of the presently disclosure and are meant to avoid obscuring of the presently disclosure.

It should be noted that the description merely illustrates the principles of the present invention. It will thus be appreciated that those skilled in the art will be able to devise various arrangements that, although not explicitly described herein, embody the principles of the present invention. Furthermore, all examples recited herein are principally intended expressly to be only for explanatory purposes to help the reader in understanding the principles of the invention and the concepts contributed by the inventor to furthering the art and are to be construed as being without limitation to such specifically recited examples and conditions. Moreover, all statements herein reciting principles, aspects, and embodiments of the invention, as well as specific examples thereof, are intended to encompass equivalents thereof.

### EXAMPLES

Illustrative examples of the technologies disclosed herein are provided below. A configuration of the technologies may include any one or more, and any combination of, the examples described below.

Example 1 is a method in a test and measurement instrument including measuring noise at an output of a power supply, measuring jitter of a serial data signal produced by a data generating circuit coupled to the power supply, and correlating the noise measured from the power supply to the jitter of the serial data signal.

Example 2 is a method according to Example 1, further including generating a first spectral plot display in a frequency domain of the measured noise spanning a range of frequencies, generating a second spectral plot display in the frequency domain of the measured jitter spanning the same range of frequencies, presenting the first spectral plot display and the second spectral plot display on an output display screen.

Example 3 is a method according to Example 2 in which the range of frequencies is user specified.

Example 4 is a method according to any preceding Example, in which correlating the noise measured from the power supply to the jitter of the serial data signal comprises searching noise components of the output of the power supply through a range of frequencies, searching jitter components of the serial data signal through the same range of frequencies, and determining particular frequencies within the range of frequencies for which the noise components of the output of the power supply exceed a first threshold and for which the jitter components of the serial data signal exceed a second threshold.

Example 5 is a method according to any preceding Example, further including applying a generated stress signal to the power supply at a particular frequency.

Example 6 is a method according to any preceding Example, in which measuring noise at an output of a power supply comprises measuring ripple.

Example 7 is a method according to any preceding Example, in which measuring jitter of a serial data signal comprises measuring time interval error.

Example 8 is a method according to any preceding Example, further including measuring vertical noise of the serial data signal, and correlating the noise measured from the power supply to the vertical noise of the serial data signal.

Example 9 is a method according to any preceding Example, further including applying a notch filter to the serial data signal to generate a filtered serial data signal, and displaying a visual output of the filtered serial data signal.

Example 10 is a method according to Example 9, in which parameters for the notch filter are configurable by a user of the test and measurement instrument.

Example 11 is a method according to Example 9, in which in which displaying a visual output of the filtered serial data signal comprises generating an eye diagram of the filtered serial data signal, generating a spectral plot display of the filtered serial data signal, or generating a histogram of the filtered serial data signal.

Example 12 is a method according to Example 9, further including displaying a visual output of the serial data signal prior to applying the notch filter.

Example 13 is a method according to Example 9, further including further including determining an amount of increase of opening of an eye diagram produced from the serial data signal before and after application of the notch filter, and presenting the determined amount of improvement on a display.

Example 14 is a method according to any preceding Example, in which correlating the noise measured from the power supply to the jitter of the serial data signal comprises comparing ripple measured from the power supply to time interval error of the serial data at particular frequencies.

Example 15 is a method according to Example 14 in which only ripple measured from the power supply that is greater than a threshold amount of ripple is used in the correlation.

Example 16 is a method according to any preceding Example, in which only ripple measured from the power supply at less than a pre-defined frequency is used in the correlation.

Example 17 is a method according to any preceding Example, further including presenting a series of interactive screens to a user of the test and measurement instrument.

Example 18 is a method according to Example 17, in which the series of interactive screens accepts a voltage ripple frequency from the user, and in which the voltage ripple is applied to the power supply at the accepted ripple frequency.

Example 19 is a method according to Example 17 in which the test and measurement instrument is coupled to a Device Under Test that includes the power supply and the data generating circuit, and in which the series of interactive screens accepts input from a user defining an input channel of the test and measurement instrument that is coupled to the power supply, and accepts input from the user defining an input channel of the data generating circuit.

Example 20 is a test and measurement system, including a Device Under Test (DUT) to be tested, the DUT including a power supply and a serial data generator that uses power supplied by the power supply, and a test and measurement instrument coupled to the DUT, and including an input channel for receiving a power supply signal from the power supply of the DUT, another input channel for receiving the serial data signal generated by the DUT, a measurement unit structured to measure noise of the power supply signal and to measure jitter of the serial data signal generated by the DUT, a processor structured to correlate the noise measured from the power supply to the jitter of the serial data signal, and a display structured to show the results of the correlation.

Example 21 is a test and measurement system according to Example 20, in which the results of the correlation includes a first spectral plot display in a frequency domain of the power supply noise spanning a range of frequencies, and a second spectral plot display in the frequency domain of the jitter spanning the same range of frequencies.

Example 22 is a test and measurement system according to Example 17 in which the processor of the test and measurement instrument is structured to apply a notch filter to the serial data signal to generate a filtered serial data signal, and in which the display is structured to display a visual output of the filtered serial data signal.

Example 23 is a test and measurement system according to Example 22, in which the visual output of the filtered serial data signal comprises an eye diagram of the filtered serial data signal, a spectral plot display of the filtered serial data signal, or a histogram of the filtered serial data signal.

Example 24 is a test and measurement system according to Example 22, in which the processor is structured to determine an amount of increase of opening of an eye diagram display produced from the serial data signal before and after application of the notch filter, and in which the display is structured to show results of the determination.

Example 25 is a test and measurement system according to any of the Examples 20-24, in which the test and measurement instrument includes a memory for storing a series of interactive screens on the display that are relevant to measuring noise of the power supply and jitter on the serial data signal.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

What is claimed is:

1. A method in a test and measurement instrument comprising:
measuring noise at an output of a power supply;
measuring jitter of a serial data signal produced by a data generating circuit coupled to the power supply; and
correlating the noise measured from the power supply to the jitter of the serial data signal.

2. The method in a test and measurement instrument according to claim 1, further comprising:
generating a first spectral plot display in a frequency domain of the measured noise spanning a range of frequencies;
generating a second spectral plot display in the frequency domain of the measured jitter spanning the same range of frequencies; and
presenting the first spectral plot display and the second spectral plot display on an output display screen.

3. The method in a test and measurement instrument according to claim 2, in which the range of frequencies is user specified.

4. The method in a test and measurement instrument according to claim 1, in which correlating the noise measured from the power supply to the jitter of the serial data signal comprises:
searching noise components of the output of the power supply through a range of frequencies;
searching jitter components of the serial data signal through the same range of frequencies; and
determining particular frequencies within the range of frequencies for which the noise components of the output of the power supply exceed a first threshold and for which the jitter components of the serial data signal exceed a second threshold.

5. The method in a test and measurement instrument according to claim 1, further comprising applying a generated stress signal to the power supply at a particular frequency.

6. The method in a test and measurement instrument according to claim 1, in which measuring noise at an output of a power supply comprises measuring ripple.

7. The method in a test and measurement instrument according to claim 1, in which measuring jitter of a serial data signal comprises measuring time interval error.

8. The method in a test and measurement instrument according to claim 1, further comprising:
measuring vertical noise of the serial data signal; and
correlating the noise measured from the power supply to the vertical noise of the serial data signal.

9. The method in a test and measurement instrument according to claim 1, further comprising:
applying a notch filter to the serial data signal to generate a filtered serial data signal; and
displaying a visual output of the filtered serial data signal.

10. The method in a test and measurement instrument according to claim 9, in which parameters for the notch filter are configurable by a user of the test and measurement instrument.

11. The method in a test and measurement instrument according to claim 9, in which displaying a visual output of the filtered serial data signal comprises generating an eye diagram of the filtered serial data signal, generating a spectral plot display of the filtered serial data signal, or generating a histogram of the filtered serial data signal.

12. The method in a test and measurement instrument according to claim 9, further comprising displaying a visual output of the serial data signal prior to applying the notch filter.

13. The method in a test and measurement instrument according to claim 9, further comprising:
determining an amount of increase of opening of an eye diagram produced from the serial data signal before and after application of the notch filter; and
presenting the determined amount of improvement on a display.

14. The method in a test and measurement instrument according to claim 1, in which correlating the noise measured from the power supply to the jitter of the serial data signal comprises comparing ripple measured from the power supply to time interval error of the serial data at particular frequencies.

15. The method in a test and measurement instrument according to claim 14, in which only ripple measured from the power supply that is greater than a threshold amount of ripple is used in the correlation.

16. The method in a test and measurement instrument according to claim 1, in which only ripple measured from the power supply at less than a pre-defined frequency is used in the correlation.

17. The method in a test and measurement instrument according to claim 1, further comprising presenting a series of interactive screens to a user of the test and measurement instrument.

18. The method in a test and measurement instrument according to claim 17, in which the series of interactive screens accepts a voltage ripple frequency from the user, and in which the voltage ripple is applied to the power supply at the accepted ripple frequency.

19. The method in a test and measurement instrument according to claim 17, in which the test and measurement instrument is coupled to a Device Under Test that includes the power supply and the data generating circuit, and in which the series of interactive screens accepts input from a user defining an input channel of the test and measurement instrument that is coupled to the power supply, and accepts input from the user defining an input channel of the data generating circuit.

20. A test and measurement system, comprising:
a Device Under Test (DUT) to be tested, the DUT including a power supply and a serial data generator that uses power supplied by the power supply; and
a test and measurement instrument coupled to the DUT, and including:
an input channel for receiving a power supply signal from the power supply of the DUT;
another input channel for receiving the serial data signal generated by the DUT;
a measurement unit structured to measure noise of the power supply signal and to measure jitter of the serial data signal generated by the DUT;
a processor structured to correlate the noise measured from the power supply to the jitter of the serial data signal; and
a display structured to show the results of the correlation.

21. The test and measurement system according to claim 20, in which the results of the correlation comprises:
a first spectral plot display in a frequency domain of the power supply noise spanning a range of frequencies; and
a second spectral plot display in the frequency domain of the jitter spanning the same range of frequencies.

22. The test and measurement system according to claim 17, in which the processor of the test and measurement instrument is structured to apply a notch filter to the serial data signal to generate a filtered serial data signal, and in which the display is structured to display a visual output of the filtered serial data signal.

23. The test and measurement system according to claim 22, in which the visual output of the filtered serial data signal comprises an eye diagram of the filtered serial data signal, a spectral plot display of the filtered serial data signal, or a histogram of the filtered serial data signal.

24. The test and measurement system according to claim 22, in which the processor is structured to determine an amount of increase of opening of an eye diagram display produced from the serial data signal before and after application of the notch filter, and in which the display is structured to show results of the determination.

25. The test and measurement system according to claim 20, in which the test and measurement instrument includes a memory for storing a series of interactive screens on the display that are relevant to measuring noise of the power supply and jitter on the serial data signal.
